(19) United States
(12) Patent Application Publication
(10) Pub. No.: US 2007/0228391 A1
(43) Pub. Date: Oct. 4, 2007

(54) Light emitting device

(75) Inventors: Yukimura Minami, Aichi-ken (JP); Makoto Ishida, Aichi-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: TOYODA GOSEI CO., LTD., Aichi-ken (JP)

(21) Appl. No.: 11/727,398

(22) Filed: Mar. 26, 2007

(30) Foreign Application Priority Data
Mar. 29, 2006 (JP) 2006-089944

(51) Int. Cl. H01L 33/00

(52) U.S. Cl. 257/79

(57) ABSTRACT

A light emitting device has an LED (light emitting diode) element, and a power feeding member through which electrical power is fed to the LED element, the power feeding member comprising an electrically conductive material. The power feeding member has a light reflecting layer formed on the surface of the power feeding member, the light reflecting layer being formed of a metal, and a protecting layer formed on the surface of the light reflecting layer, the protecting layer being formed of an organic compound.

The present application is based on Japanese patent application No. 2006-089944 filed on Mar. 29, 2006, the entire contents of which are incorporated herein by reference.

### BACKGROUND OF THE INVENTION

1. Field of the Invention

This invention relates to a light emitting device that is formed of a light emitting diode (LED), and uses as a light reflecting layer a power feeding member through which to feed electrical power to the LED and, in particular, to a light emitting device that, in case of using silicone based materials to seal the power feeding member, can prevent discoloration of the light reflecting layer to enhance the long-term reliability of the light emitting device.

2. Description of the Related Art

Conventionally, a light emitting element formed of gallium nitride (GaN) is known as one of group III nitride-based compound semiconductor light emitting elements. Since the GaN type light emitting element has a light emitting property to emit light from an ultraviolet region to a visible region and can provide a white light with high brightness by wavelength-converting by using a wavelength-conversion means such as phosphors, various ideas to use the GaN type light emitting element as a white light source have been proposed.

It is known that a light reflecting layer is formed on the surface of the feeding member, e.g., a lead portion, so as to reflect back light emitted to directions other than its regular light emitting direction (i.e., the vertical direction of LED) to take out the emitted light efficiently outside the package to enhance the brightness of the light emitting device using the GaN type light emitting element.

For example, a light reflecting layer formed of silver (Ag) in a surface-mounted type light emitting device using a lead portion formed of copper (Cu) can be formed by plating on the surface of the lead portion exposed at an element mounting portion where to mount an LED element to reflect back light entering into the plated surface of the lead portion.

However, in the light reflecting layer formed of metal, there is a disadvantage that the reflection coefficient may be decreased when the light reflecting layer is discolored due to heat or gas penetrating through the sealing material. The light emitting devices using the LED element conventionally have used epoxy resin as the sealing material. However, in recent years, silicone based resin materials have been often used as the sealing material in order to cope with high brightness and high output of the LED element. Although the silicone based rein materials are superior in thermal resistance and light resistance than the epoxy resin, they also are different from the epoxy resin in that they have relatively high gas penetration characteristics, and need to use platinum as a curing catalyst. Based on the above differences, there are many problems in replacing the sealing material from the epoxy resin to the silicone based resin materials. In case of using the silicone based resin materials as the sealing material, it has been recently pointed out as a problem that the long-term reliability becomes difficult to keep due to the significant discoloration (i.e., decrease in reflection coefficient) of the light reflecting layer. The light reflecting layer can be formed of at least one of gold, silver, copper, palladium, aluminum, rhodium, chromium, nickel and tin. Of them, Ag is particularly subject to deterioration.

To solve the above disadvantages, a method of coating a film on an Ag plated terminal for an electrode to prevent discoloration as an Ag discoloration preventing film is known (e.g., JP-A-02-298084).

However, the light emitting device using the LED element in JP-A-02-298084 has only advantages in using epoxy resin as a sealing material. Recently, as described above, to cope with the high brightness and high output of the LED element, the silicone based resin materials are often used as the sealing material. Further, in light emitting devices using the GaN type LED element with notably required high brightness and high output, there is a tendency that according as the amount of fed current increases, the amount of heat generated also increases, and, when selecting an organic compound with the discoloration preventing effect, it is necessary to consider adequately whether it has a stable bond to the light reflecting layer formed of metal and it has a good thermal resistance.

### SUMMARY OF THE INVENTION

It is an object of the invention to provide a light emitting device that can prevent discoloration of the light reflecting layer formed of metal to enhance the long-term reliability, in case of using silicone-based resin materials as a sealing material in the light emitting device with an LED element.

According to one aspect of the invention, a light emitting device comprises:

an LED (light emitting diode) element; and

a power feeding member through which electrical power is fed to the LED element, the power feeding member comprising an electrically conductive material,

wherein the power feeding member comprises a light reflecting layer formed on a surface of the power feeding member, the light reflecting layer comprising a metal, and a protecting layer formed on a surface of the light reflecting layer, the protecting layer comprising an organic compound.

In the above invention, the following modifications and changes can be made.

(i) The LED (light emitting diode) element comprises a group III nitride-based compound semiconductor.

(ii) The LED (light emitting diode) element comprises a group III nitride-based compound semiconductor, and

the organic compound comprises at least one of triazole, imidazole, triazine, thiazole, mercaptan, thiocyanic acid, benzole, silicate, titanate, amine, carbonyl, and tetrazole.

(iii) The light emitting device further comprises a silicone-based resin material sealing the power feeding member.

(iv) The light reflecting layer comprising at least one of silver, gold, copper, palladium, aluminum, rhodium, chromium, nickel and tin. Of these metals, silver is most preferable since it has a high reflection coefficient to blue light.

(v) The light emitting device further comprises a silicone-based resin material sealing the power feeding member, wherein the light reflecting layer comprises at least one of silver, gold, copper, palladium, aluminum, rhodium, chromium, nickel and tin.

(vi) The organic compound comprises at least one of benzotriazole compound, triazole compound, thiocyanic acid based compound, silane compound, titanium compound, triazine compound, benzoimidazole compound, imidazole compound, compound containing mercaptocarboxylic acid and/or salts thereof, thiazole compound, benzothiazole compound, thionalide, oxazole compound, thiol compound, tetrazole compound, alkylaminotriazoles compound, higher alkylamine compound, ethyleneoxide adduct of higher alkylamine compound, α-dicarbonyl compound, amine adduct of α-dicarbonyl, β-dicarbonyl compound, and amine adduct of β-dicarbonyl.

(vii) The organic compound comprises at least one of benzotriazole compound, triazole compound, thiocyanic acid based compound, silane compound, titanium compound, triazine compound, benzoimidazole compound, imidazole compound, compound containing mercaptocarboxylic acid and/or salts thereof, thiazole compound, benzothiazole compound, thionalide, oxazole compound, and thiol compound.

(viii) The silicone-based resin material comprises a phosphor that allows the device to emit a white light.

Advantages of the Invention

By the invention, the protecting layer can have a stable bond to the light reflecting layer, and can keep its discoloration preventing effect for the light reflecting layer even under high heat load to enhance the long-term reliability of the light emitting device.

### BRIEF DESCRIPTION OF THE DRAWINGS

The preferred embodiments according to the invention will be explained below referring to the drawings, wherein:

FIG. 1A is a longitudinal cross sectional view showing a light emitting device of surface-mounted type in a first preferred embodiment according to the invention;

FIG. 1B is a longitudinal cross sectional view showing a light emitting element;

FIG. 1C is an enlarged cross sectional view showing a lead portion in FIG.1A;

FIG. 2 is a longitudinal cross sectional view showing a light emitting device of surface-mounted type in a second preferred embodiment according to the invention; and

FIG. 3 is a longitudinal cross sectional view showing a light emitting device of bullet type in a third preferred embodiment according to the invention.

### DETAILED DESCRIPTION OF THE PREFERRED EMBODIMENTS

### First embodiment

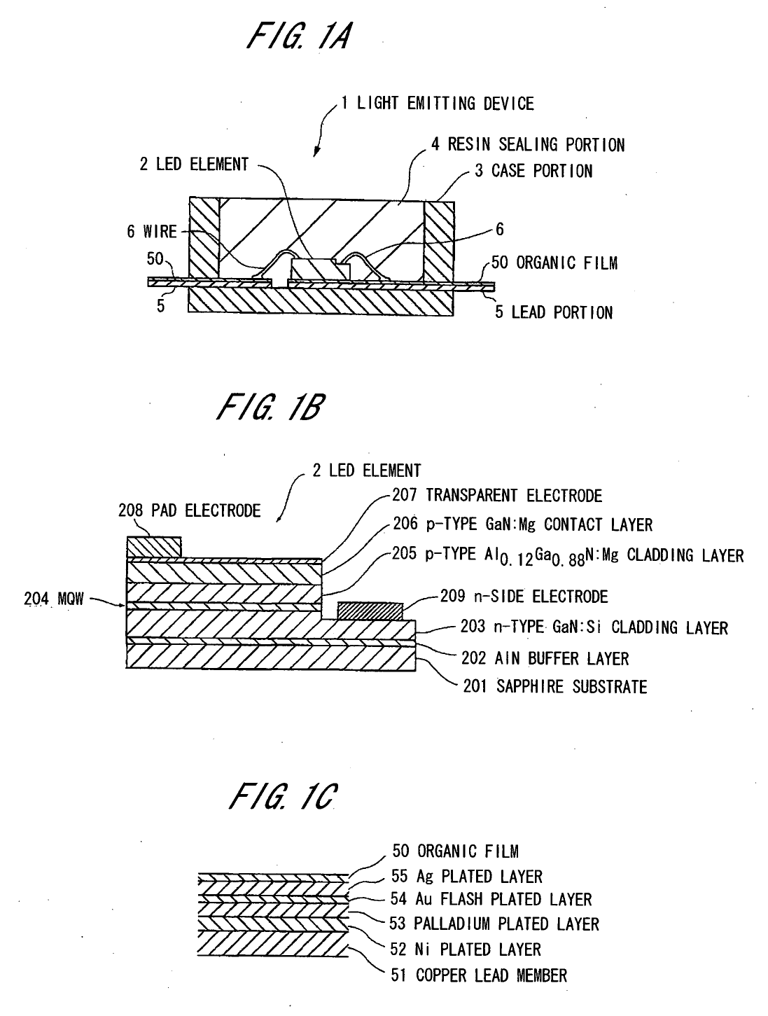

FIG. 1A is a longitudinal cross sectional view showing a light emitting device of surface-mounted type in a first preferred embodiment according to the invention, FIG. 1B is a longitudinal cross sectional view showing a light emitting element, and FIG. 1C is an enlarged cross sectional view showing a lead portion in FIG. 1A.

The light emitting device 1 comprises a LED element 2 formed on a sapphire substrate by a crystal growth of a GaN-based semiconductor layer, a case portion 3 formed of white resin or ceramics comprising a light reflectivity, a resin sealing portion 4 sealing an opening portion of the case portion 3 housing the LED element 2, a lead portion 5 for feeding electrical power to the LED element 2 housed in the case portion 3, the lead portion 5 comprising a Ag plated layer as a light reflecting layer formed on the surface thereof and an organic film 50 formed of organic compounds and formed on the surface of the light reflecting layer as a protecting layer, wires 6 formed of gold (Au) and electrically connecting n-side and p-side electrodes of the LED element 2 and the lead portion as a feeding member.

As shown in FIG. 1B, the LED element 2 is a horizontal LED element where p-side and n-side electrodes are disposed in a horizontal direction, and is formed by a sequentially multi-layered structure comprising a sapphire substrate 201 being a growth substrate for growing III group nitride based compounds thereon, a AlN buffer layer 202 formed on the sapphire substrate 201, a n-type GaN:Si cladding layer 203 doped with Si, a MQW 204 having a multiquantum well structure of InGaN/GaN, a p-type Al_{0.12}Ga_{0.88}N:Mg cladding layer 205 doped with Mg, a p-type GaN:Mg contact layer206 doped with Mg, and a transparent electrode 207 comprising ITO (Indium Tin Oxide) and diffusing electrical current to the p-type GaN: Mg contact layer 206, and the layers from the AlN buffer layer 202 to the p-type GaN:Mg contact layer 206 are formed by the MOCVD (Metal Organic Chemical Vapor Deposition) method.

Further, a pad electrode 208 comprising Au is formed on a surface of the transparent electrode 207, and a n-side electrode 209 comprising Al is formed on the n-type GaN:Si cladding layer 203 where from the p-type GaN:Mg contact layer 206 to the n-type GaN:Si cladding layer 203 in the light emitting element portion are eliminated by etching process.

The MQW 204 has 4 pairs of an InGaN well layer and a GaN barrier layer, but it can have 3 to 6 pairs thereof.

The light emitting device 1 emits a blue light having a peak wavelength of 460 to 465 nm, when an electrical power is fed to the pad electrode 208 and the n-side electrode 209 from outside, so as to produce an electron-positive hole recombination in the InGaN well layer in the MQW 204 of the LED element 2. The blue light passes through the resin sealing portion 4 and emits to outside of the case portion 3.

The case 3 comprises a resin material such as nylon, acrylic resin or a ceramic material such as alumina, and comprises TiO₂ as a light reflective material to enhance a reflection efficiency of the blue light emitted from the LED element 2 housed in the opening portion formed in therein. Further, Ba can be mixed other than TiO₂ as the light reflective material.

The resin sealing portion 4 comprises silicone and functions so as to seal the LED element 2 housed in the opening portion of the case portion 3 and the lead portion 5 exposed in the opening portion.

As shown in FIG. 1C, the lead portion 5 is formed by a sequentially multi-layered structure comprising a copper lead member 51, and a Ni plated layer 52, a palladium plated layer 53, a Au flash plated layer 54 and a Ag plated layer 55 on the surface of the copper lead member 51, and an organic film 50 formed of organic compounds is formed on the surface of the Ag plated layer 55. The organic film 50 is obtained by forming the Ag plated layer 55, immersing in a bathtub filled with liquid comprising the selected organic compounds, and washing with water and drying.

The organic film 50 functions so as to surface-treat the Ag plated surface by organic compounds comprising at least one composition selected from the group consisting of triazole, imidazole, triazine, thiazole, mercaptan, thiocyanic acid, benzole, silicate, titanate, amine, carbonyl, and tetrazole.

In particular, the organic compounds comprise at least one compound selected from the group consisting of benzotriazole compound, triazole compound, thiocyanic acid based compound, silane compound, titanium compound, triazine compound, benzoimidazole compound, imidazole compound, compound comprising mercaptocarboxylic acid and/or the salts, thiazole compound, benzothiazole compound, thionalide, oxazole compound, thiol compound, tetrazole compound, alkylaminotriazoles compound, higher alkylamine compound, ethyleneoxide adduct of higher alkylamine compound, α-dicarbonyl compound, amine adduct of α-dicarbonyl, β-dicarbonyl compound, and amine adduct of β-dicarbonyl, of them, the organic compounds comprise preferably at least one compound selected from the group consisting of benzotriazole compound, triazole compound, thiocyanic acid based compound, silane compound, titanium compound, triazine compound, benzoimidazole compound, imidazole compound, compound comprising mercaptocarboxylic acid and/or the salts, thiazole compound, benzothiazole compound, thionalide, oxazole compound, and thiol compound, of them, the organic compounds comprise more preferably at least one compound selected from the group consisting of benzotriazole compound, triazole compound, thiocyanic acid based compound, silane compound, benzoimidazole compound, imidazole compound, thiazole compound, benzothiazole compound, and thiol compound.

### Advantages of the First Embodiment

According to the first preferred embodiment of the invention described above, the organic film 50 formed of organic compounds is formed on the surface of the lead portion 5 so as to realize a stable connection with the Ag plated layer 55 and inhibit chemical change in the Ag surface, so that a light emitting device comprising a good light reflectivity for long periods can be obtained.

Further, in the first preferred embodiment, a light emitting device 1 emitting a blue light emitted from a LED element 2 formed of III group nitride based compounds has been explained, but for example, a light emitting device 1 of wavelength conversion type can be used, the device 1 comprising a resin sealing portion 4 formed of silicone which contains yellow phosphors such as YAG (Yttrium Aluminum Garnet) to emit a white light based on mixture of a blue light emitted from the LED element 2 and a yellow light obtained by exciting the phosphors by the blue light.

### Second Embodiment

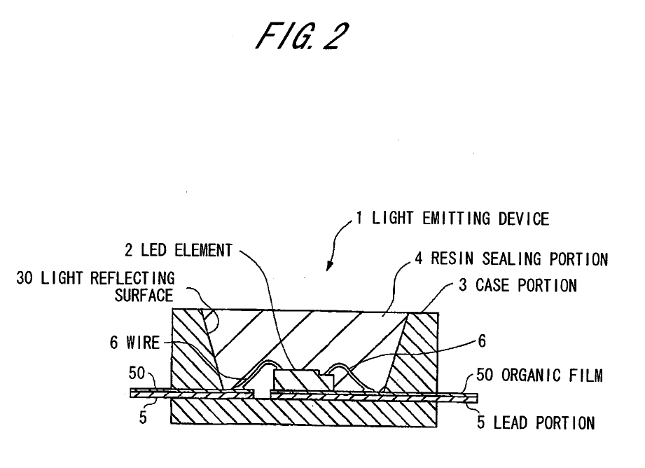

FIG.2 is a longitudinal cross sectional view showing a light emitting device of surface-mounted type in a second preferred embodiment according to the invention.

The light emitting device 1 in the second preferred embodiment is different from the device of the first preferred embodiment in that the device 1 comprises a light reflecting surface 30 inclined to the inside of the case portion 3, so as to enhance an outward taking out efficiency by reflecting the light emitted from the LED element 2 and entering the light reflecting surface 30 in the direction based on the inclined angle.

Further, a light reflective film comprising light reflective materials such as aluminum (Al) can be formed on the light reflecting surface 30.

### Advantages of the Second Embodiment

According to the second preferred embodiment of the invention described above, in addition to the preferred advantages of the first preferred embodiment, the blue light emitted from the LED element 2 is reflected on the light reflecting surface 30 of the case portion 3 so as to emit the light outward efficiently, so that a light emitting device 1 with high brightness can be obtained.

### Third Embodiment

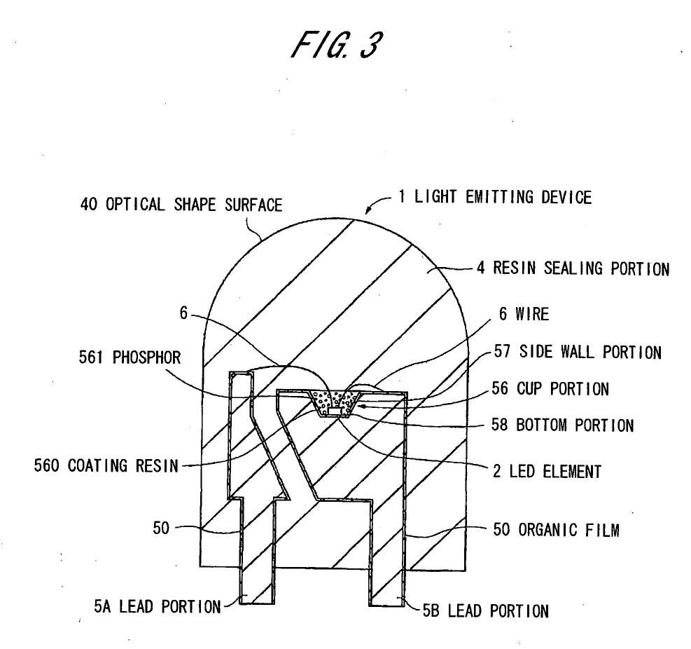

FIG.3 is a longitudinal cross sectional view showing a light emitting device of bullet type in a third preferred embodiment according to the invention.

The light emitting device 1 in the third preferred embodiment comprises lead portions 5A, 5B comprising copper alloy superior to thermal conductivity, the LED element 2 to emit a blue light, being fixed in a cup portion 56 formed on the lead portion 5B by impression process, a wire 6 electrically connecting electrodes of the LED element 2 and the lead portions 5A, 5B, a coating resin 560 comprising silicone containing a phosphor 561 to emit a yellow light when excited by a blue light, and sealing the cup portion 56 in which the LED element 2 is housed, and a resin sealing portion 4 comprising transparent and colorless epoxy resin, integrally sealing the lead portions 5A, 5B and the wire 6.

The cup portion 56 comprises the side wall portion 57 formed at a slant so as to reflect the blue light emitted from the LED element 2 in the light taking out direction, and the bottom portion 58 mounting the LED element 2, and is formed by impression process at press-work of the lead portion 5B.

Ag plated layer (not shown) to provide a light reflectivity to the surface is formed on the lead portions 5A, 5B, and the organic film 50 formed of organic compounds explained in the first preferred embodiment is formed on the surface of the lead portions 5A, 5B.

The resin sealing portion 4 comprises an optical shape surface 40 of hemispheroidal shape at the top portion conforming to the light taking out direction, collects the light emitted from the LED element 2 based on the optical shape, and emits the light in the emission coverage according to the optical shape. The resin sealing portion 4 can be formed by a casting mold method of housing a lead frame comprising the lead portion 5A and the lead portion 5B mounting the LED element 2 and wire-bonded in a die assembly, and filling epoxy resin in the die assembly for thermal hardening.

### Advantages of the Third Embodiment

According to the third preferred embodiment described above, in addition to the preferred advantages of the first preferred embodiment, also in the light emitting device 1 of bullet type, the organic film 50 inhibits the discoloration of the Ag plated layer formed on the lead portion 5 for long periods, so that decrease in the brightness can be prevented.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

For example, as to the organic film 50 formed on the lead portion 5, in each of the preferred embodiments a case that the organic film 50 comprises a kind of organic film has been explained, but the multi-layered organic film 50 comprising not less than 2 kinds of organic films can also be used. Further, a case that the light emitting device 1 comprises one LED element 2 has been explained in each of the preferred embodiments, but the organic film 50 can also be used to the light emitting device 1 comprising a plurality of LED elements 2 as measures for preventing discoloration of the light reflecting layer formed of metal.

Further, thickness of the light reflecting layer formed of metal, kind of metal of the substrate, and layer composition between the substrate and the light reflecting layer formed of metal are not limited to the preferred embodiments described above. And, a method for forming the organic film (discoloration preventing layer) 50 is not limited, but selected organic compounds can be added to a plating solution, the selected organic compounds can be sprayed after forming the light reflecting layer formed of metal (e.g. the Ag plated layer 55), or the selected organic compounds can be added to sealing material, die attach material, or case resin to expect breeding effect to an interface between the light reflecting layer formed of metal and the sealing resin. It is not necessary that the organic film (discoloration preventing layer) 50 is formed just after the Ag plated layer 55 is formed, and the film can be formed on only a necessary portion, instead of being formed on the all surface.

What is claimed is:

1. A light emitting device, comprising:
an LED (light emitting diode) element; and
a power feeding member through which electrical power is fed to the LED element, the power feeding member comprising an electrically conductive material,
wherein the power feeding member comprises a light reflecting layer formed on a surface of the power feeding member, the light reflecting layer comprising a metal, and a protecting layer formed on a surface of the light reflecting layer, the protecting layer comprising an organic compound.

2. The light emitting device according to claim 1, wherein:
the LED (light emitting diode) element comprises a group III nitride-based compound semiconductor.

3. The light emitting device according to claim 1, wherein: the LED (light emitting diode) element comprises a group III nitride-based compound semiconductor, and
the organic compound comprises at least one of triazole, imidazole, triazine, thiazole, mercaptan, thiocyanic acid, benzole, silicate, titanate, amine, carbonyl, and tetrazole.

4. The light emitting device according to claim 1, further comprising:
a silicone-based resin material sealing the power feeding member.

5. The light emitting device according to claim 1, wherein:
the light reflecting layer comprises at least one of silver, gold, copper, palladium, aluminum, rhodium, chromium, nickel and tin.

6. The light emitting device according to claim 1, further comprising:
a silicone-based resin material sealing the power feeding member,
wherein the light reflecting layer comprises at least one of silver, gold, copper, palladium, aluminum, rhodium, chromium, nickel and tin.

7. The light emitting device according to claim 1, wherein:
the organic compound comprises at least one of benzotriazole compound, triazole compound, thiocyanic acid based compound, silane compound, titanium compound, triazine compound, benzoimidazole compound, imidazole compound, compound containing mercaptocarboxylic acid and/or salts thereof, thiazole compound, benzothiazole compound, thionalide, oxazole compound, thiol compound, tetrazole compound, alkylaminotriazoles compound, higher alkylamine compound, ethyleneoxide adduct of higher alkylamine compound, α-dicarbonyl compound, amine adduct of α-dicarbonyl, β-dicarbonyl compound, and amine adduct of β-dicarbonyl.

8. The light emitting device according to claim 1, wherein:
the organic compound comprises at least one of benzotriazole compound, triazole compound, thiocyanic acid based compound, silane compound, titanium compound, triazine compound, benzoimidazole compound, imidazole compound, compound containing mercaptocarboxylic acid and/or salts thereof, thiazole compound, benzothiazole compound, thionalide, oxazole compound, and thiol compound.

9. The light emitting device according to claim 4, wherein:
the silicone-based resin material comprises a phosphor that allows the device to emit a white light.

10. The light emitting device according to claim 6, wherein:
the silicone-based resin material comprises a phosphor that allows the device to emit a white light.
